(19) United States
(12) Patent Application Publication
(10) Pub. No.: US 2022/0406568 A1
(43) Pub. Date: Dec. 22, 2022

(54) PLASMA PROCESSING METHOD AND PLASMA PROCESSING APPARATUS

(71) Applicant: Tokyo Electron Limited, Tokyo (JP)

(72) Inventor: Gen TAMAMUSHI, Kurokawa-gun (JP)

(21) Appl. No.: 17/846,734

(22) Filed: Jun. 22, 2022

(30) Foreign Application Priority Data
Jun. 22, 2021 (JP) 2021-103283

(51) Int. Cl. H01J 37/32

(52) U.S. Cl. CPC H01J 37/32146; H01J 37/32715; H01J 2237/334

(57) ABSTRACT

A plasma processing method for plasma-processing a substrate with a plasma processing apparatus having a substrate support and an upper electrode inside a chamber, the method comprising: placing the substrate on the substrate support; supplying a processing gas for processing the substrate to the chamber; supplying a radio frequency to the upper electrode or the substrate support to generate plasma from the processing gas inside the chamber; periodically applying a first pulse voltage to the substrate support in a first cycle during a period in which the radio frequency is being supplied; and periodically applying a second pulse voltage to the upper electrode in a second cycle during the period in which the radio frequency is being supplied.

### BACKGROUND

An exemplary embodiment of the present disclosure relates to a plasma processing method and a plasma processing apparatus.

### RELATED ART

The processing method described in Patent Document 1 is a technique for suppressing a decline in the substrate etching rate.

[Patent Document 1] JP 2019-036658 A

### SUMMARY

An exemplary embodiment of the present disclosure provides a plasma processing method for plasma-processing a substrate with a plasma processing apparatus. The plasma processing apparatus including a chamber, a substrate support provided inside the chamber and configured to support the substrate, and an upper electrode provided inside the chamber opposite the substrate support, and the substrate processing method comprises a step of placing a substrate on the substrate support, a step of supplying a processing gas for processing the substrate to the chamber, a step of supplying a radio frequency to the upper electrode or the substrate support and generating plasma from the processing gas inside the chamber, a first application step of periodically applying a first pulse voltage to the substrate support in a first cycle during a period in which the radio frequency is being supplied, and a second application step of periodically applying a second pulse voltage to the upper electrode in a second cycle that is 1/n of the first cycle during the period in which the radio frequency is being supplied.

Another exemplary embodiment of the present disclosure provides a plasma processing apparatus. The plasma processing apparatus comprises a chamber, a substrate support provided inside the chamber and configured to support the substrate, an upper electrode provided inside the chamber opposite the substrate support, and a control unit, and the control unit executes controls to place a substrate on the substrate support, supplying a processing gas for processing the substrate to the chamber, supplying a radio frequency to the upper electrode or the substrate support and generating plasma from the processing gas inside the chamber, periodically applying a first pulse voltage to the substrate support in a first cycle during a period in which the radio frequency is being supplied, and periodically applying a second pulse voltage to the upper electrode in a second cycle that is 1/n of the first cycle during the period in which the radio frequency is being supplied.

### BRIEF DESCRIPTION OF THE DRAWINGS

FIG. 1 is a figure schematically illustrating the substrate processing apparatus 1 in an exemplary embodiment of the present disclosure.

FIG. 2 is a partially enlarged view of the substrate support 11 in the substrate processing apparatus 1.

FIG. 3 is a flowchart showing the substrate processing method in an exemplary embodiment of the disclosure.

FIG. 4 is a timing chart showing the periods during which a source RF signal, a first DC signal, and a second DC signal are supplied or applied and stopped.

FIG. 5 is a timing chart showing an example of the timing for periodically applying the first pulse voltage and the second pulse voltage.

FIG. 6 is a timing chart showing an example of the timing for periodically applying the first pulse voltage and the second pulse voltage.

FIG. 7 is a timing chart showing an example of the timing for periodically applying the first pulse voltage and the second pulse voltage.

FIG. 8 is a timing chart showing an example of the timing for periodically applying the first pulse voltage and the second pulse voltage.

FIG. 9 is a timing chart showing an example of the timing for periodically applying the first pulse voltage and the second pulse voltage.

FIG. 10 is a timing chart showing an example of the timing for periodically applying the first pulse voltage and the second pulse voltage.

FIG. 11 is a timing chart showing an example of the timing for periodically applying the first pulse voltage and the second pulse voltage.

### DETAILED DESCRIPTION

Embodiments of the present disclosure will now be described.

In an exemplary embodiment, a plasma processing method for plasma-processing a substrate with a plasma processing apparatus having a substrate support and an upper electrode inside a chamber is provided. The method comprises: placing the substrate on the substrate support; supplying a processing gas for processing the substrate to the chamber; supplying a radio frequency to the upper electrode or the substrate support to generate plasma from the processing gas inside the chamber; periodically applying a first pulse voltage to the substrate support in a first cycle during a period in which the radio frequency is being supplied; and periodically applying a second pulse voltage to the upper electrode in a second cycle during the period in which the radio frequency is being supplied.

In an exemplary embodiment, in the periodically applying the second pulse voltage, the second pulse voltage is applied to the upper electrode in synchronization with the applying the first pulse voltage.

In an exemplary embodiment, the second cycle is 1/n of the first cycle.

In an exemplary embodiment, n is 1.

In an exemplary embodiment, n is 2 or more.

In an exemplary embodiment, the substrate support that is provided inside the chamber is configured to support the substrate.

In an exemplary embodiment, the upper electrode positioned inside the chamber is opposite the substrate support.

In an exemplary embodiment, the periodically applying the first pulse voltage includes: starting application of the first pulse voltage at a first point in time, and ending application of the first pulse voltage at a second point in time after the first point in time, and the periodically applying the second pulse voltage includes: starting application of the second pulse voltage at the first point in time, and ending application of the second pulse voltage at the second point in time.

In an exemplary embodiment, the periodically applying the first pulse voltage includes: starting application of the first pulse voltage at a first point in time, and ending application of the first pulse voltage at a second point in time after the first point in time, and the periodically applying the second pulse voltage includes: starting application of the second pulse voltage between the first point in time and the second point in time, and ending application of the second pulse voltage at a point in time later than the second point in time.

In an exemplary embodiment, the periodically applying the first pulse voltage includes: starting application of the first pulse voltage at a first point in time, and ending application of the first pulse voltage at a second point in time after the first point in time, and the periodically applying the second pulse voltage includes: starting application of the second pulse voltage at the second point in time, and ending application of the second pulse voltage at a second point in time after the second point in time.

In an exemplary embodiment, periodically applying the first pulse voltage includes: starting application of the first pulse voltage at a first point in time, and ending application of the first pulse voltage at a second point in time after the first point in time, and the periodically applying the second pulse voltage includes: starting application of the second pulse voltage at a third point in time after the second point in time, and ending application of the second pulse voltage at a point in time after the third point in time.

In an exemplary embodiment, a time interval from the start to the end of application of the second pulse voltage is equal to the time interval from the start to the end of application of the first pulse voltage.

In an exemplary embodiment, a time interval from the start to the end of application of the second pulse voltage is longer than the time interval from the start to the end of application of the first pulse voltage.

In an exemplary embodiment, a time interval from the start to the end of application of the second pulse voltage is shorter than the time interval from the start to the end of application of the first pulse voltage.

In an exemplary embodiment, in the generating the plasma, the radio frequency is supplied to the substrate support.

In an exemplary embodiment, in the periodically applying the first pulse voltage, negative voltage is applied to the substrate support as the first pulse voltage.

In an exemplary embodiment, in the periodically applying the second pulse voltage, negative voltage is applied to the substrate support as the second pulse voltage.

In an exemplary embodiment, a plasma processing apparatus is provided. The apparatus comprises: a chamber; a substrate support provided inside the chamber and configured to support the substrate; an upper electrode provided inside the chamber opposite the substrate support; and a control unit, wherein the control unit executes controls to place a substrate on the substrate support, the controls comprising: supplying a processing gas for processing the substrate to the chamber, supplying a radio frequency to the upper electrode or the substrate support and generating plasma from the processing gas inside the chamber, periodically applying a first pulse voltage to the substrate support in a first cycle during a period in which the radio frequency is being supplied, and periodically applying a second pulse voltage to the upper electrode in a second cycle during the period in which the radio frequency is being supplied.

In an exemplary embodiment, the second cycle is 1/n of the first cycle.

In an exemplary embodiment, n is 1, or 2 or more.

The following is a detailed description of embodiments of the present disclosure with reference to the drawings. In the drawings, identical or similar elements are denoted by the same reference numbers and redundant descriptions of these elements have been omitted. In the following description, positional relationships such as up, down, left and right are based on the positional relationships shown in the drawings except where otherwise specified. The dimensional ratios in the drawings do not indicate actual ratios, and the actual ratios are not limited to the ratios shown in the drawings.

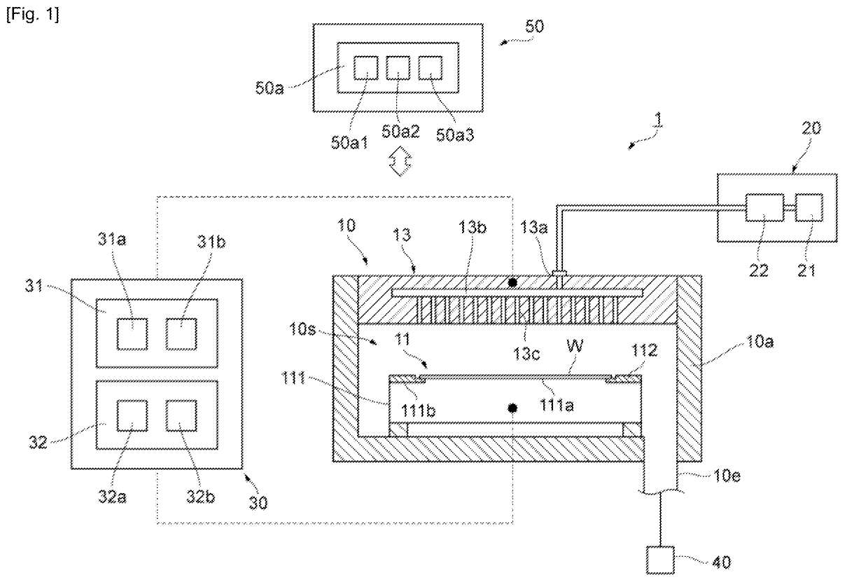

FIG. 1 is a figure schematically illustrating the substrate processing apparatus 1 in an exemplary embodiment of the present disclosure. The substrate processing apparatus 1 is a capacitively coupled plasma processing apparatus. The substrate processing apparatus 1 includes a plasma processing chamber 10, a gas supplying unit 20, a power supply 30, an exhaust system 40, and a control unit 50. The substrate processing apparatus 1 also includes a substrate support 11 and a gas introducing unit. The gas introducing unit is configured to introduce at least one processing gas to the plasma processing chamber 10. The gas introducing unit includes a shower head 13. The substrate support 11 is arranged inside the plasma processing chamber 10. The shower head 13 is arranged above the substrate support 11. In an exemplary embodiment, the shower head 13 constitutes at least a portion of the ceiling of the plasma processing chamber 10. The plasma processing chamber 10 has a plasma processing space 10s defined by a shower head 13, the side walls 10a of the plasma processing chamber 10, and a substrate support 11. The plasma processing chamber 10 has at least one gas supply port for supplying at least one processing gas to the plasma processing space 10s, and at least one gas discharge port for discharging gas from the plasma processing space. The side walls 10a are grounded. The shower head 13 and the substrate support 11 are electrically isolated from the housing of the plasma processing chamber 10.

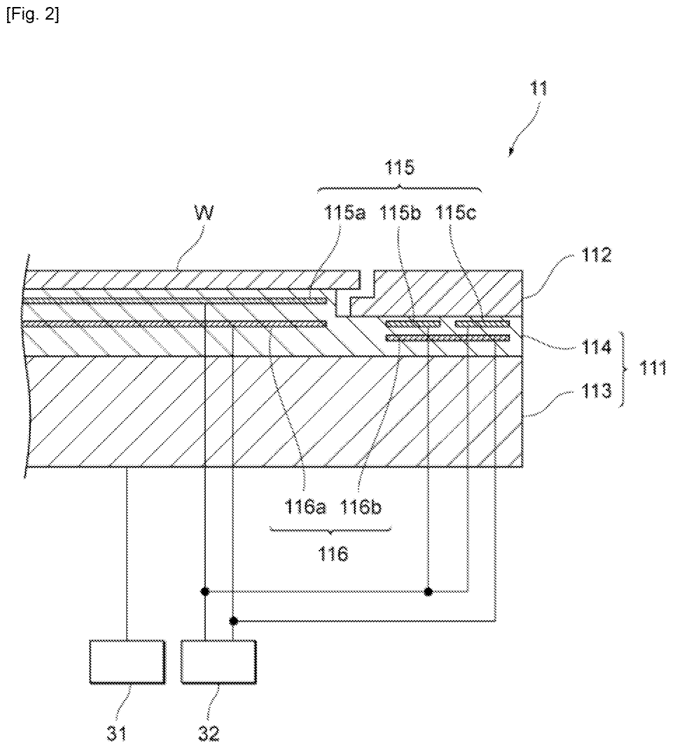

FIG. 2 is a partially enlarged view of the substrate support 11 in the substrate processing apparatus 1. The substrate support 11 includes a main body 111 and a ring assembly 112. The main body 111 includes a base 113 and an electrostatic chuck 114. The main body 111 also has a central region (substrate supporting surface) 111a for supporting the substrate (wafer) W and an annular region (ring supporting surface) 111b for supporting the ring assembly 112. The annular region 111b of the main body 111 surrounds the central region 111a of the main body 111 in a plan view. The substrate W is arranged in the central region 111a of the main body 111, and the ring assembly 112 is arranged in the annular region 111b of the main body 111 so as to surround the substrate W in the central region 111a of the main body 111. The base 113 may include a conductive member. The conductive member of the base 113 can function as the lower electrode. The electrostatic chuck 114 is arranged on the base. The upper surface of the electrostatic chuck 114 has a substrate supporting surface 111a. The ring assembly 112 includes one or more annular members. At least one of the one or more annular members is an edge ring.

The electrostatic chuck 114 includes a chuck electrode 115 and a bias electrode 116 on the inside. The chuck electrode 115 has an electrode 115a provided between the substrate supporting surface 111a and the base 113. The electrode 115a may be a planar electrode that conforms to the shape of the substrate supporting surface 111a. The chuck electrode 15 may also have electrodes 115b, 115c provided between the ring assembly 112 and the base 113. The electrodes 115b, 115c may be annular electrodes that conform to the shape of the ring assembly 112. An electrode 115c is also provided to the outside of electrode 115b. The bias electrode 116 has an electrode 116a provided between electrode 115a (or the substrate supporting surface 111a) and the base 113. The electrode 116a may be a planar electrode that conforms to the shape of the substrate supporting surface 111a and/or the electrode 115a. The bias electrode 116 may also have an electrode 116b provided between the ring assembly and the base 113.

When the conductive member included in the base 113 functions as the lower electrode, the electrostatic chuck 114 does not have to include a bias electrode 116. The chuck electrode 115 may also function as the lower electrode. When the chuck electrode 115 functions as the lower electrode, the electrostatic chuck 114 does not have to include a bias electrode 116. In the electrostatic chuck 114, the portion including electrodes 115a and 116a and the portion including electrodes 115b, 115c, and 116b may be configured as separate components.

Although not shown in the figures, the substrate support 11 may include a temperature control module configured to adjust at least one of the electrostatic chuck 114, ring assembly 112, and substrate to the target temperature. The temperature control module may include a heater, a heat transfer medium, a flow path, or any combination of these. A heat transfer fluid such as brine or gas flows along the flow path. The substrate support 11 may also include a heat transfer gas supplying unit configured to supply a heat transfer gas between the back surface of the substrate W and the substrate supporting surface 111a.

Returning to FIG. 1, the shower head 13 is configured to introduce at least one processing gas from the gas supplying unit 20 into the plasma processing space 10s. The shower head 13 has at least one gas supply port 13a, at least one gas diffusing chamber 13b, and a plurality of gas introduction ports 13c. The processing gas supplied to the gas supply port 13a passes through the gas diffusing chamber 13b and is introduced into the plasma processing space 10s from the plurality of gas introduction ports 13c. The shower head 13 also includes a conductive member. The conductive member in the shower head 13 functions as the upper electrode. In addition to the shower head 13, the gas introducing unit may include one or a plurality of side gas injectors (SGI) attached to one or a plurality of openings formed in the side walls 10a.

The gas supplying unit 20 may include at least one gas source 21 and at least one flow rate controller 22. In an exemplary embodiment, the gas supplying unit 20 is configured to supply at least one processing gas from a corresponding gas source 21 to the shower head 13 via a corresponding flow rate controller 22. Each flow rate controller 22 may include, for example, a mass flow controller or a pressure control-type flow rate controller. The gas supplying unit 20 may also include one or more flow rate modulating devices that modulate or pulse the flow rate of at least one processing gas.

The power supply 30 includes an RF power supply 31 coupled to the plasma processing chamber 10 via at least one impedance matching circuit. The RF power supply 31 is configured to supply an RF signal (RF power) that is at least one of a source RF signal and a biased RF signal to a conductive member in the substrate support 11 and/or to a conductive member in the shower head 13. As a result, plasma is formed from at least one processing gas supplied to the plasma processing space 10s. Thus, the RF power source 31 may function as at least portion of a plasma generating unit configured to generate plasma from one or more processing gases in the plasma processing chamber 10. Also, by supplying a bias RF signal to a conductive member in the substrate support 11, a bias potential can be generated in the substrate W to attract the ion component of the plasma toward the substrate W.

In an exemplary embodiment, the RF power supply 31 includes a first RF generating unit 31a and a second RF generating unit 31b. The first RF generating 31a is coupled to a conductive member in the substrate support 11 and/or a conductive member in the shower head 13 via at least one impedance matching circuit and is configured to generate a source RF signal (source RF power) for generating plasma. In an exemplary embodiment, the source RF signal is composed of radio frequency continuous or pulsed waves with a frequency in the range of 13 MHz to 150 MHz. In an exemplary embodiment, the first RF generating unit 31a may be configured to generate multiple source RF signals with different frequencies. The generated source RF signals are supplied to the conductive member in the substrate support 11 and/or shower head 13. The one or more source RF signals may be supplied to the base 113, the chuck electrode 115, or the bias electrode 116 in the substrate support 11. The second RF generating unit 31b is coupled to the conductive member in the substrate support 11 via at least one impedance matching circuit and is configured to generate bias RF signals (bias RF power). In an exemplary embodiment, the biased RF signals have a lower frequency than the source RF signals. In an exemplary embodiment, the bias RF signal is composed of radio frequency continuous or pulsed waves with a frequency in the range of 400 kHz to 13.56 MHz. In an exemplary embodiment, the second RF generating unit 31b may be configured to generate multiple biased RF signals with different frequencies. The one or more generated bias RF signals are supplied to the base 113, the chuck electrode 115, or the bias electrode 116 in the substrate support 11. In various embodiments, at least one of the source RF signal and the bias RF signal may be pulsed.

The power supply 30 may include a DC power supply 32 coupled to the plasma processing chamber 10. The DC power supply 32 includes a first DC generation unit 32a and a second DC generation unit 32b. In an exemplary embodiment, the first DC generating unit 32a is connected to the conductive member in the substrate support 11 and is configured to generate a first DC signal. The generated first bias DC signal is applied to the conductive member in the substrate support 11. In an exemplary embodiment, the first DC signal may be applied to the base 113 in the substrate support 11, or to electrode 116a and/or electrode 116b in the chuck electrode 115 or bias electrode 116. In an exemplary embodiment, the second DC generating unit 32b is connected to the conductive member of the shower head 13 and is configured to generate the second DC signal. The generated second DC signal is applied to the conductive member in the shower head 13. In various embodiments, at least one of the first and second DC signals may be pulsed. The first and second DC generating units 32a, 32b may be provided in addition to the RF power supply 31, and the first DC generating unit 32a may be provided instead of the second RF generation unit 31b. In addition, the first DC signal and the second DC signal may be generated so that one frequency is a multiple of the other frequency. For example, the second DC generating unit 31b may generate the second DC signal in synchronization with the period for the first DC signal. The first DC signal and the second DC signal can have a frequency of, for example, 400 kHz. Also, the first DC signal and the second DC signal may be generated to synchronize with the period for the source RF signal and/or the bias RF signal.

The DC power supply 32 generates DC voltage applied to the electrodes 115a, 115b, 115c in the chuck electrode 115 (see FIG. 2). The electrodes 115b, 115c may constitute a bipolar electrostatic chuck. The electrodes 115a, 115b, 115c may also be configured integrally. The DC power supply 32 may be configured to apply different DC voltages to the electrodes 115a, 115b, 115c, or may be configured to apply the same DC voltage. The power supply 30 may have a power supply that generates voltage applied to the chuck electrode 115 in addition to the DC power supply 32.

The exhaust system 40 can be connected, for example, to a gas outlet 10e provided at the bottom of the plasma processing chamber 10. The exhaust system 40 may include a pressure regulating valve and a vacuum pump. The pressure control valve regulates the pressure inside the plasma processing space 10s. The vacuum pump may include a turbo molecular pump, a dry pump, or a combination of these.

The control unit 50 processes computer-executable instructions that get the substrate processing apparatus 1 to perform the steps described in the present disclosure. The control unit 50 may be configured to get each unit in the substrate processing apparatus 1 to perform the steps described in the present specification. In an exemplary embodiment, some or all of the control unit 50 may be provided as part of the configuration of a device external to the substrate processing apparatus 1. The control unit 50 may include, for example, a computer 50a. The computer 50a may include, for example, a central processing unit (CPU) 50a1, a storage unit 50a2, and a communication interface 50a3. The processing unit 50a1 may be configured to perform control operations based on a program stored in the storage unit 50a2. The storage unit 50a2 may include random access memory (RAM), read-only memory (ROM), a hard disk drive (HDD), a solid state drive (SSD), or a combination of these. The communication interface 50a3 may communicate with other configurations in the substrate processing apparatus 1 via a communication line such as a local area network (LAN).

Note that instead of capacitively coupled plasma (CCP), the plasma formed in the plasma processing space may be inductively coupled plasma (ICP), electron-cyclotron-resonance (ECR) plasma, helicon wave plasma (HWP), or surface wave plasma (SWP). Other types of plasma generating units that may be used include altemating current (AC) plasma generating units and direct current (DC) plasma generating units. In one embodiment, the AC signals (AC power) used by the AC plasma generating unit have a frequency in the range of 100 kHz to 10 GHz. Therefore, AC signals include RF (Radio Frequency) signals and microwave signals. In one embodiment, the RF signals have frequencies in the range of 200 kHz to 150 MHz.

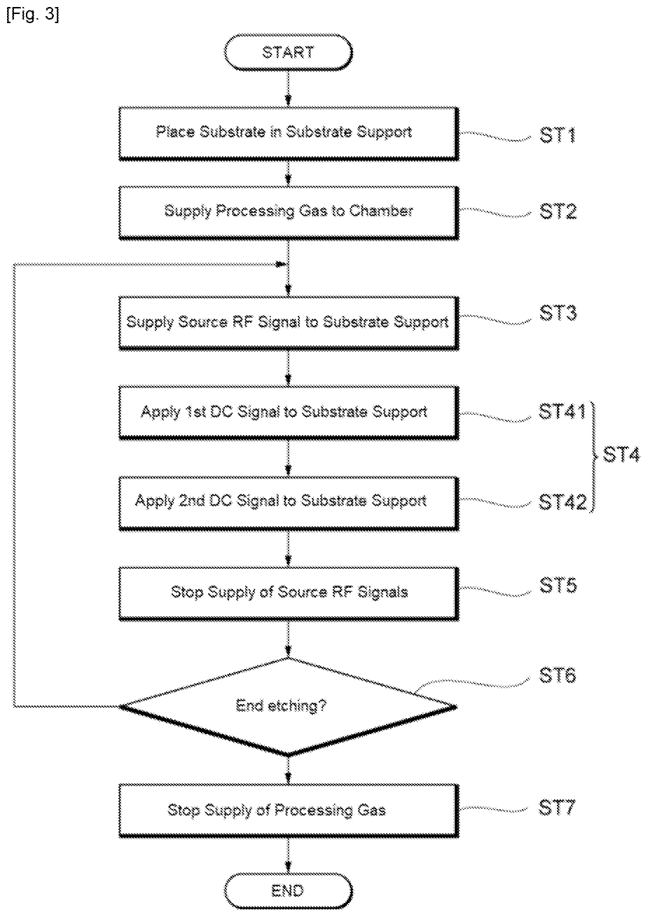

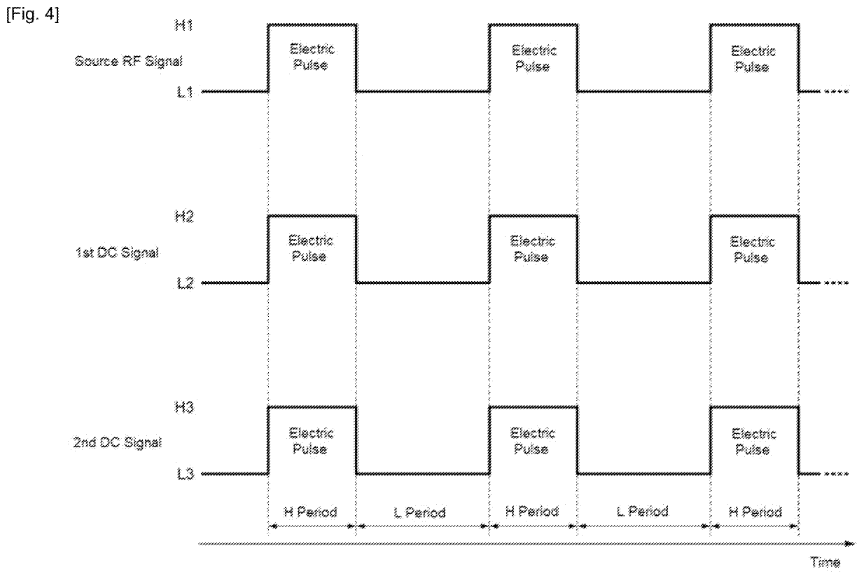

FIG. 3 is a flowchart showing the substrate processing method (“the processing method” below) in an exemplary embodiment of the disclosure. FIG. 4 is a timing chart showing the periods during which a source RF signal, a first DC signal, and a second DC signal are supplied or applied and stopped.

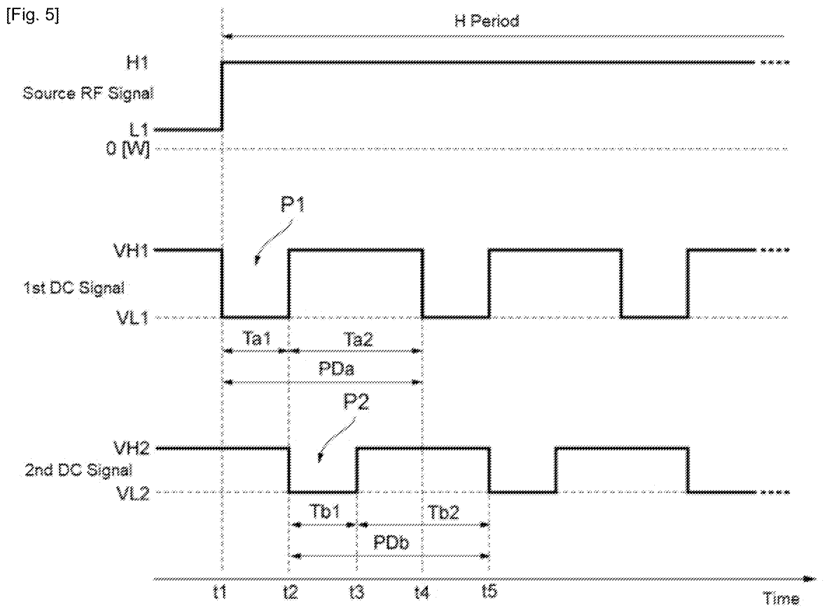

FIG. 4 shows an example in which pulse waves are used by the source RF signal and both the first DC signal and the second DC signal. For example, the source RF signal may consist of a pulse wave including an electric pulse in the H period. The first DC signal and the second DC signal may also consist of pulse waves including an electric pulse in the H period. In FIG. 4, the horizontal axis indicates time. In FIG. 5, the vertical axis indicates the power level of the source RF signal (for example, the effective value of the power in the source RF signal) and the voltage level of the first DC signal and the second DC signal (for example, the effective value of the absolute value of the voltage of the first DC signal and the second DC signal). Here, “L1” in the source RF signal indicates that the source RF signal is not being supplied or is lower than the power level indicated by “H1.” The “L2” and “L3” for the first DC signal and the second DC signal indicate either the first DC signal and the second DC signal are not being supplied, or are lower than the voltage levels indicated by “H2” and “H3.”

The processing method (see FIG. 3) has a step of placing a substrate W on the substrate support 11 (ST1), a step of supplying processing gas to the plasma processing chamber 10 (ST2), a step of supplying a source RF signal (an example, a radio frequency signal) to the lower electrode (ST3), the step of applying the pulse voltage (ST4), the step of stopping supply of the source RF signal (ST5), a step of determining the end of etching (ST6), and a step of stopping the supply of processing gas (ST7).

In step ST1, the substrate W is placed on the substrate support 11. The substrate W may be, for example, a silicon wafer on which a base film, the film to be etched using the processing method, and a mask film with a predetermined pattern have been laminated. The film to be etched may be, for example, a dielectric film, a semiconductor film, or a metal film.

In step ST2, the processing gas is supplied to the plasma processing chamber 10. The processing gas is a gas used to etch the film to be etched that has been formed on the substrate W. The type of processing gas used may be selected based on the material constituting the film to be etched, the material constituting the mask film, the material constituting the undercoat film, the pattern formed in the mask film, and/or the etching depth.

In step ST3, the source RF signal is supplied to the substrate support 11. The source RF signal consists of a pulse wave with an electrical pulse in the H period (see FIG. 4). Each electric pulse in the source RF signal is configured to include a radio frequency continuous wave. The radio frequency is, for example, a frequency in the range of 13 MHz to 150 MHz. When a source RF signal is supplied to the substrate support 11, plasma is formed from the processing gas supplied to the plasma processing chamber 10. In other embodiments, the source RF signal may be supplied to an upper electrode in the shower head 13.

In step ST4, an electric pulse is applied to the upper electrode and the substrate support 11. Step ST4 includes a step of applying a first DC signal to the substrate support 11 (ST41) and a step of applying a second DC signal to the upper electrode in the shower head 13 (ST42). Step ST3, step ST41 and step ST42 may be started at the same time or at different times.

The first DC signal is a pulse wave with an electrical pulse in the H period. In other words, in step ST41, the electric pulse in the first DC signal is periodically applied to the substrate support 11.

The second DC signal is a pulse wave with an electrical pulse in the H period. In other words, in step ST42, the electric pulse in the second DC signal is periodically applied to the upper electrode.

In step ST5, the source RF signal being supplied to the substrate support 11 is stopped. With this, the H period ends as L period starts in which the supply of the source RF signal is stopped (see FIG. 4). The power of the source RF signal in the L period is lower than the power of the source RF signal in the H period. Also, in the L period, the power of the source RF signal may be 0 W (watts). The supply of the first pulse voltage P1 and the second pulse voltage P2 may also be stopped in the L period.

In step ST6, it is determined whether or not to end etching of the film to be etched. When the etching process is continued, the process returns to ST3 and the H period is started again. When the etching process is to be ended, supply of processing gas is stopped in step ST7, and the etching process is ended.

FIG. 5 to FIG. 11 are timing charts showing examples of the timing for periodically applying the first pulse voltage P1 and the second pulse voltage P2 in the H period. The relationship between the source RF signal and the first DC signal and the second DC signal in step ST4 (see FIG. 3) will now be described with reference to FIG. 5 to FIG. 11.

In FIG. 5 to FIG. 11, the horizontal axis indicates time. The amplitude in the timing chart indicates the power of the source RF signal, the voltage of the first DC signal, and the voltage of the second DC signal. In the H period shown in FIG. 5 to FIG. 11, the power of the source RF signal changes at a constant frequency (for example, a frequency within the range of 13 MHz to 150 MHz).

In the examples shown in FIG. 5 to FIG. 11, the first DC signal is a square wave whose voltage is VH1 or VL. The second DC signal is a square wave whose voltage is VH2 or VL2. In the following explanation, the voltage of the first DC signal becoming VL1 is sometimes referred to as “applying the first pulse voltage P1,” and the pulse itself in the first DC signal is sometimes referred to as the “first pulse voltage P1.” Also, the voltage of the second DC signal becoming VL2 is sometimes referred to as “applying the second pulse voltage P2,” and the pulse itself in the second DC signal is sometimes referred to as the “second pulse voltage P2.” Note that the waveform indicated by one or more pulse voltages P1 in the first DC signal and/or the waveform indicated by one or more pulse voltages P1 in the second DC signal may be that of a triangular wave, trapezoidal wave, or impulse instead of a square wave. Any signal may be used as long as the voltage changes at regular intervals and a predetermined bias voltage can be applied to the upper electrode or the substrate support 11. Also, voltage VH1 and voltage VH2 may be 0 V, and voltage VL1 and voltage VL2 may be negative voltages.

The example in FIG. 5 will now be explained. As shown in FIG. 5, the voltage of the first DC signal becomes VL1 and the first pulse voltage P1 is applied to the substrate support 11 based on the start of the H period at time t1. The first pulse voltage P1 is applied to the substrate support 11 from the time t1 to time t2 (time period Ta1). When the first pulse voltage P1 is applied to the substrate support 11, the active species in the plasma are attracted toward the substrate W placed on the substrate support 11. As a result, the active species collide with the film to be etched that was formed on the substrate W, and the film is etched.

When application of the first pulse voltage P1 is stopped at time t2, application of the second pulse voltage P2 is started. Application of the second pulse voltage P2 may be started based on the end of application of the first pulse voltage P1. The second pulse voltage P2 is applied to the upper electrode during time period Tb1 from time t2 to time t3.

When time period Ta2 from time t2 has elapsed at time t4, time period PDa, which forms one cycle of the first DC signal, comes to an end. At time t4, the voltage of the first DC signal reaches VL1 again, and the next cycle of the first DC signal starts. When time period Tb2 from time t3 has elapsed at the time t5, time period PDb, which forms one cycle of the second DC signal, comes to an end. At time t5, the voltage of the second DC signal reaches VL2 again, and the next cycle of the second DC signal starts. By repeating these operations, step ST4 of the present example is executed.

In the present example, when the positive ions in the plasma are attracted toward the substrate W and the film is etched during the period Ta1, the etched portion of the substrate W (for example, the bottom of a hole formed in the film to be etched) may be positively charged by positive ions. When the second pulse voltage P2 is applied to the upper electrode, the positive ions in the plasma are attracted toward the upper electrode and collide with the upper electrode. When positive ions collide with the upper electrode, secondary electrons are emitted by the upper electrode. The emitted secondary electrons are accelerated by the upper electrode which has a negative potential (voltage V2) and reach the substrate W. The secondary electrons that reach the substrate W eliminate or reduce the charge in the positively charged portion of the substrate W (for example, the bottom of a hole formed in the film to be etched).

In the present example, the voltage VH2 of the second DC signal may be 0 V during time period Ta1. As a result, emission of secondary electrons from the upper electrode is suppressed in time period Ta1, and the potential of the upper electrode suppresses the acceleration of electrons in the direction of the substrate W. As a result, during time period Ta1, the surrounding surface of the substrate W is kept from becoming negatively charged by electrons. As a result, the secondary electrons emitted from the upper electrode during time period Tb1 do not decelerate near the surface of the substrate W, but can reach the positively charged portion of the substrate W (for example, the bottom of a hole formed in the film to be etched).

In the present example, at time t2, the second pulse voltage P2 is applied to the upper electrode around the time that application of the first pulse voltage P1 to the substrate support 11 is stopped. As a result, when the voltage of the first DC signal applied to the substrate support 11 changes from VL1 to VH1 (that is, when application of the first pulse voltage P1 is completed), a significant increase in the potentials of the substrate W and the plasma can be suppressed. Therefore, in the present example, sputtering of the inner walls of the plasma processing chamber 10 (see FIG. 1) with high potential plasma can be reduced.

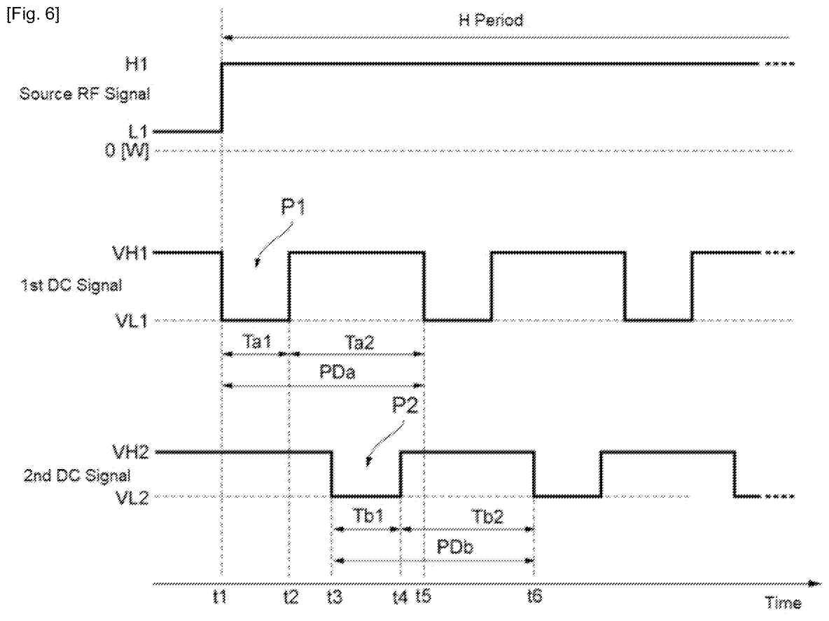

The example in FIG. 6 will now be explained. In the example shown in FIG. 6, application of the second pulse voltage P2 is started at time t3 following time t2. In other words, in the example shown in FIG. 6, there is a period between time period Ta1 and time period Tb1 in which neither the first pulse voltage P1 nor the second pulse voltage P2 is applied. Application of the second pulse voltage P2 may be started based on stoppage of the application of the first pulse voltage P1 at time t2.

In the example shown in FIG. 6, the voltage of the first DC signal is VL1 from time t1 to time t2 and VH1 from time t2 to time t5 during time period PDa which forms one cycle. During time period Ta1, which extends from time t1 to time t2, the first pulse voltage P1 is applied to the substrate support 11. During time period Ta2, which extends from time t2 to time t5, application of the first pulse voltage P1 to the substrate support 11 is stopped. With this, time period PDa, which forms one cycle of the first DC signal, comes to an end. At the same time, at time t5, the voltage of the first DC signal reaches VL1 again, and the next cycle of the first DC signal starts.

In the example shown in FIG. 6, the voltage of the second DC signal is VL2 from time t3 to time t4 and 0V from time t4 to time t6 during time period PDb, which forms one cycle. During time period Tb1, which extends from time t3 to time t4, the second pulse voltage P2 is applied to the upper electrode. During time period Tb2, which extends from time t4 to time t6, application of the second pulse voltage P2 to the upper electrode is stopped. With this, time period PDb, which forms one cycle of the second DC signal, comes to an end. Simultaneously, at time t6, the voltage of the second DC signal reaches VL2 again, and the next cycle of the second DC signal starts. By repeating these operations, step ST4 in the present example is executed.

In the present example, the second pulse voltage P2 is applied after a predetermined amount of time has passed since the end of time period Ta1 in which the first pulse voltage P1 is applied. As a result, secondary electrons are efficiently emitted by the upper electrode. Also, because the thickness of the sheath formed between the upper electrode and the plasma is increased, the extinction rate of electrons in the plasma is reduced. Therefore, the plasma density in the plasma processing chamber 10 can be efficiently increased.

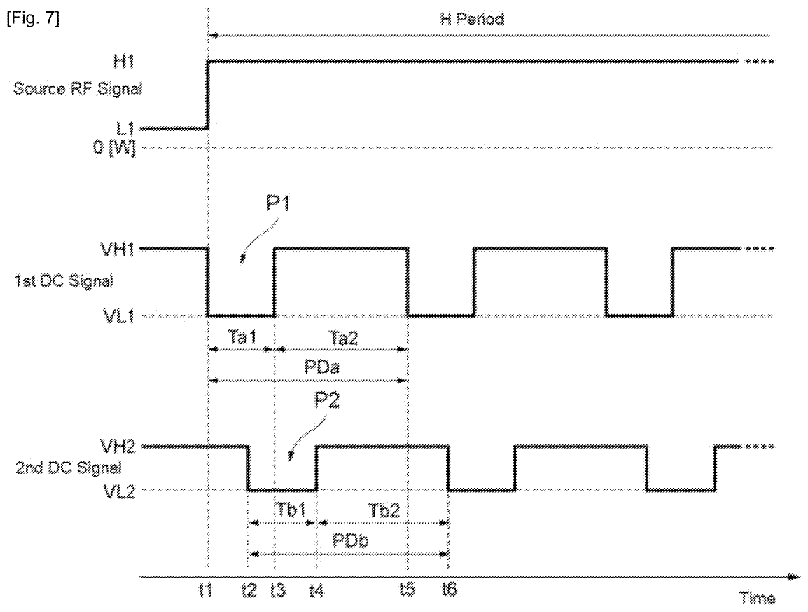

The example in FIG. 7 will now be explained. In the example shown in FIG. 7, application of the second pulse voltage P2 is started at the time t2, which is before time t3 at which time period Ta1 in which the first pulse voltage P1 is applied comes to an end. In other words, in the example shown in FIG. 7, the first pulse voltage P1 and the second pulse voltage P2 partially overlap in the time period between time t2 and time t3. Application of the second pulse voltage P2 may be started on the basis of application of the first pulse voltage P1 starting at time t1.

In the example shown in FIG. 7, the voltage of the first DC signal is VL1 from time t1 to time t3 and VH1 from time t3 to time t5 in time period PDa, which forms one cycle. In time period Ta1, which extends from time t1 to time t3, the first pulse voltage P1 is applied to the substrate support 11. In time period Ta2, which extends from time t3 to time t5, application of the first pulse voltage P1 to the substrate support 11 is stopped. With this, time period PDa, which forms one cycle of the first DC signal, comes to an end. Simultaneously, at time t5, the voltage of the first DC signal reaches VL1 again, and the next cycle of the first DC signal begins.

In the example shown in FIG. 7, the voltage of the second DC signal is VL2 from time t2 to time t4 and VH2 from time t4 to time t6 during time period PDb, which forms one cycle. In other words, during time period Tb1, which extends from time t2 to time t4, the second pulse voltage P2 is applied to the upper electrode. During time period Tb2, which extends from time t4 to time t6, application of the second pulse voltage P2 to the upper electrode is stopped. With this, time period PDb, which forms one cycle of the second DC signal, comes to an end. Simultaneously, at time t6, the voltage of the second DC signal reaches VL2 again, and the next cycle of the second DC signal begins. By repeating these operations, step ST4 in the present example is executed.

In the present example, time period Ta1 in which the first pulse voltage P1 is applied and time period Tb1 in which the second pulse voltage P2 is applied partially overlap temporally. Therefore, when time period Ta1 in which the first pulse voltage P1 is applied ends, the increase in the potentials of the substrate W and the plasma can be suppressed further. This also makes it possible to control the timing for suppressing the increase in the potentials of the substrate W and the plasma.

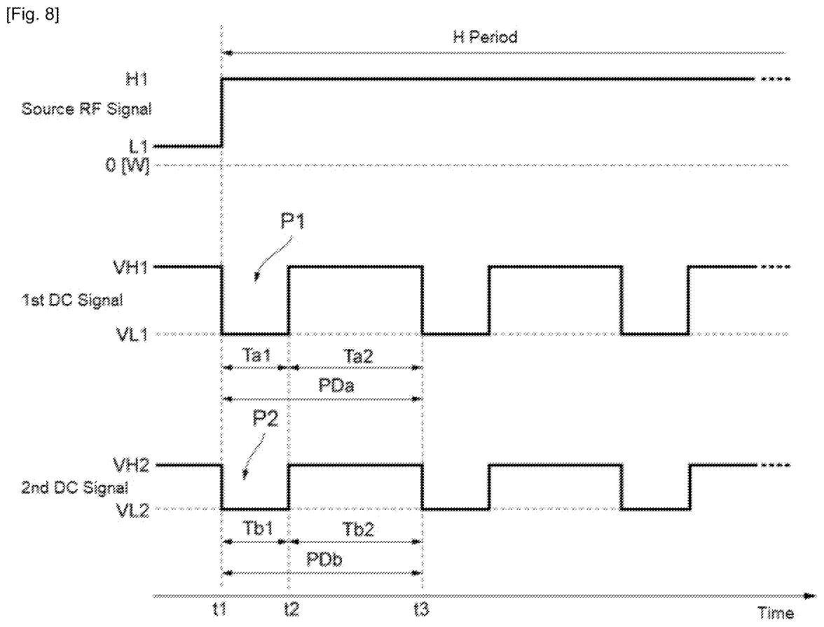

The example in FIG. 8 will now be explained. In the example shown in FIG. 8, at time t1, when the first pulse voltage P1 is applied, application of the second pulse voltage P2 begins. At time t2, when application of the first pulse voltage P1 is stopped, application of the second pulse voltage P2 also ends. In other words, in the example shown in FIG. 8, the first pulse voltage P1 and the second pulse voltage P2 are applied so as to overlap temporally. Application of the second pulse voltage P2 may be started based on application of the second pulse voltage P2 starting at time t1.

In the example shown in FIG. 8, the voltage of the first DC signal is VL1 from time t1 to time t2 and VH1 from time t2 to time t3 during time period PDa, which forms one cycle. In other words, during time period Ta1, which extends from time t1 to time t2, the first pulse voltage P1 is applied to the substrate support 11. During time period Ta2, which extends from time t2 to time t3, application of the first pulse voltage P1 to the substrate support 11 is stopped. With this, time period PDa, which forms one cycle of the first DC signal, comes to an end. Simultaneously, at time t3, the voltage of the first DC signal reaches VL1 again, and the next cycle of the first DC signal begins.

In the example shown in FIG. 8, the voltage of the second DC signal is VL2 from time t1 to time t2 and VH2 from time t2 to time t3 during time period PDb, which forms one cycle. In other words, during time period Tb1, which extends from time t1 to time t2, the second pulse voltage P2 is applied to the upper electrode. During period Tb2, which extends from time t2 to time t3, application of the second pulse voltage P2 to the upper electrode is stopped. With this, time period PDb, which forms one cycle of the second DC signal, comes to an end. Simultaneously, at time t3, the voltage of the second DC signal reaches VL2 again, and the next cycle of the second DC signal begins. By repeating these operations, step ST4 in the present example is executed.

In the present example, the second pulse voltage P2 is applied so as to overlap with time period Ta1 in which the first pulse voltage P1 is applied. This makes it possible to increase the density of the generated plasma. Also, electrons emitted from the plasma or substrate are decelerated or shielded by the sheath generated between the plasma and the upper electrode. Therefore, because the electrons, for example, can be kept from entering the gas introduction ports 13c in the shower head 13 (upper electrode), discharge at the gas introduction ports 13c can be suppressed.

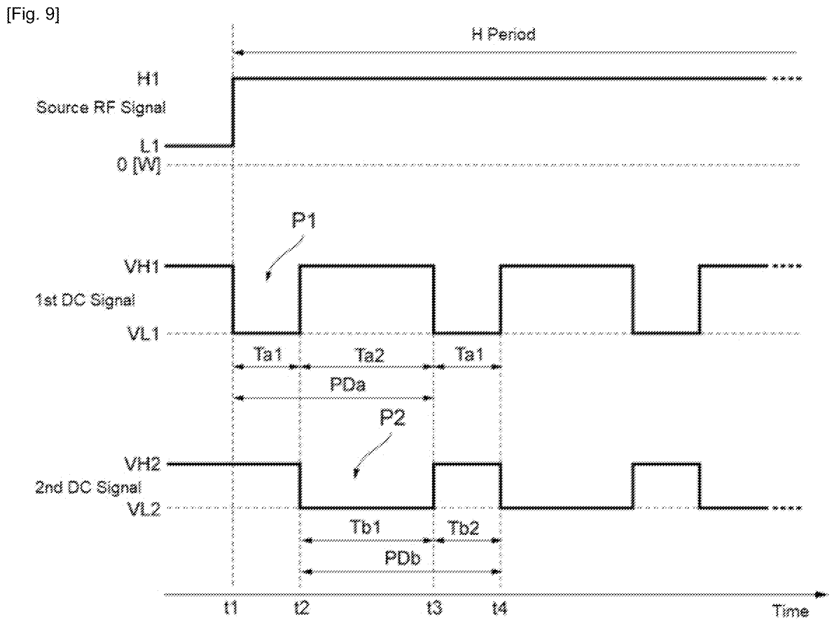

The example in FIG. 9 will now be explained. In the example shown in FIG. 9, the duty ratio of the second DC signal is different from the duty ratio of the first DC signal. In the example shown in FIG. 9, time period Ta1 in which the first pulse voltage P1 is applied is temporally aligned with time period Tb2 in which the second pulse voltage P2 is not applied. Also, time period Ta2 in which the first pulse voltage P1 is not applied is aligned with time period Tb1 in which the second pulse voltage P2 is applied. Application of the second pulse voltage P2 may be started based on the start of application of the first pulse voltage P1 at time t1. Also, application of the second pulse voltage P2 may be started based on the end of application of the first pulse voltage P1 at time t2.

In the example shown in FIG. 9, the voltage of the first DC signal is VL1 from time t1 to time t2 and VH2 from time t2 to time t3 during time period PDa, which forms one cycle. In other words, during time period Ta1 which extends from time t1 to time t2, the first pulse voltage P1 is applied to the substrate support 11. During time period Ta2, which extends from time t2 to time t3, application of the first pulse voltage P1 to the substrate support 11 is stopped. With this, time period PDa, which forms one cycle of the first DC signal, comes to an end. Simultaneously, at time t3, the voltage of the first DC signal reaches VL1 again, and the next cycle of the first DC signal begins.

Also, in the example shown in FIG. 9, the second DC signal has a voltage of VL2 from time t2 to time t3 and VH2 from time t3 to time t4 during time period PDb, which forms one cycle. In other words, during time period Tb1, which extends from time t2 to time t3, the second pulse voltage P2 is applied to the upper electrode. Also, during time period Tb2, which extends from time t3 to time t4, application of the second pulse voltage P2 to the upper electrode is stopped. With this, time period PDb, which forms one cycle of the second DC signal, comes to an end. Simultaneously, at time t4, the voltage of the second DC signal reaches VL2 again, and the next cycle of the second DC signal begins. By repeating these operations, step ST4 in the present example is executed.

In the present example, application of the second pulse voltage P2 starts in synchronization with the end of time period Ta1 in which the first pulse voltage P1 is applied, and application of the second pulse voltage P2 ends in synchronization with the start of time period Ta1 in which the first pulse voltage P1 is applied. As a result, the increase in the potentials of the substrate W and the plasma can be suppressed and the plasma density can be increased around the time t2 that application of the first pulse voltage P1 ends. Also, the secondary electrons generated in the upper electrode eliminate or further reduce the charge of the positively charged portion of the substrate W (for example, the bottom of a hole formed in the film to be etched).

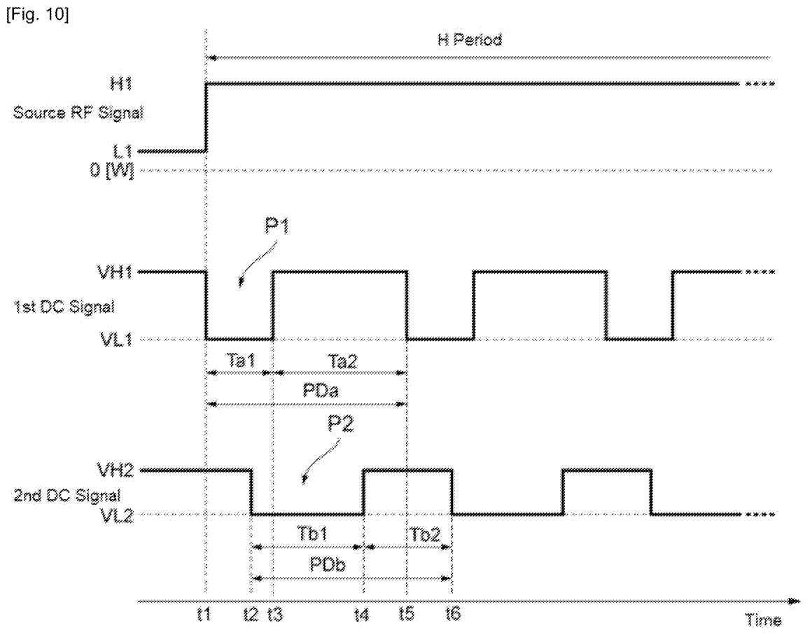

The example in FIG. 10 will now be explained. In the example shown in FIG. 10, the duty ratio of the second DC signal is different from the duty ratio of the first DC signal. Also, application of the second pulse voltage P2 is started at time t2, which is prior to time t3 at which time period Ta1 in which the first pulse voltage P1 is applied comes to an end. In other words, in the example shown in FIG. 10, there is a period between time t2 and time t3 in which the first pulse voltage P1 and the second pulse voltage P2 partially overlap. Application of the second pulse voltage P2 may be started based on the start of application of the first pulse voltage P1 at time t1.

In the example shown in FIG. 10, the voltage of the first DC signal is VL1 from time t1 to time t3 and VH1 from time t3 to time t5 during time period PDa, which forms one cycle. In other words, during time period Ta1, which extends from time t1 to time t3, the first pulse voltage P1 is applied to the substrate support 11. Also, during time period Ta2, which extends from time t3 to time t5, application of the first pulse voltage P1 to the substrate support 11 is stopped. With this, time period PDa, which is one cycle of the first DC signal, comes to an end. Simultaneously, at time t5, the voltage of the first DC signal reaches VL1 again, and the next cycle of the first DC signal begins.

Also, in the example shown in FIG. 10, the voltage of the second DC signal is VL2 from time t2 to time t4 and VH2 from time t4 to time t6 during time period PDb, which forms one cycle. In other words, during time period Tb1, which extends from time t2 to time t4, the second pulse voltage P2 is applied to the upper electrode. Also, during time period Tb2, which extends from time t4 to time t6, application of the second pulse voltage P2 to the upper electrode is stopped. As a result, time period PDb, which forms one cycle of the second DC signal, comes to an end. Simultaneously, at time t6, the voltage of the second DC signal reaches VL2 again, and the next cycle of the second DC signal begins. By repeating these operations, step ST4 in the present example is executed.

In the present example, time period Ta1 in which the first pulse voltage P1 is applied and time period Ta2 in which the second pulse voltage P2 is applied partially overlap. In this way, when time period Ta1 in which the first pulse voltage P1 is applied comes to an end, the increase in the potentials of the substrate W and the plasma can be further suppressed. This also makes it possible to control the timing for suppressing the increase in the potentials of the substrate W and the plasma. The plasma density can be further increased by the second pulse voltage P2 applied in time period Tb1.

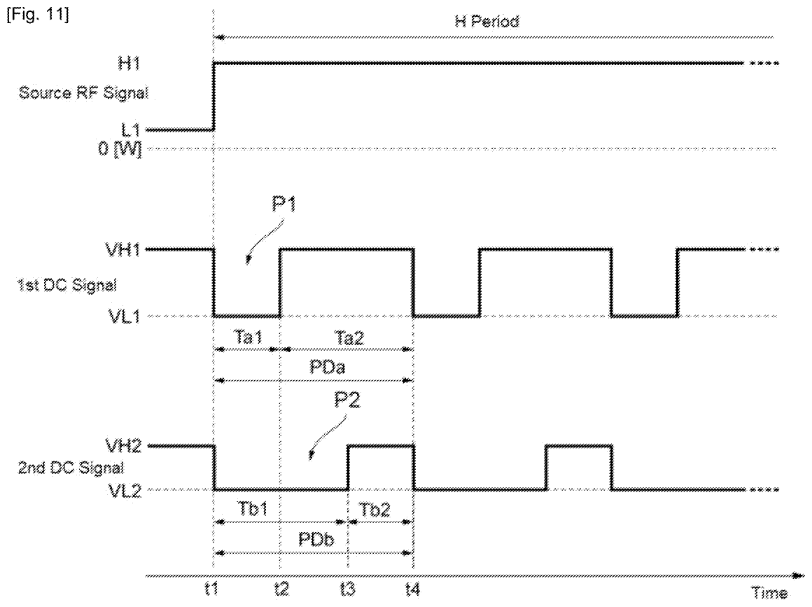

The example in FIG. 11 will now be explained. In the example shown in FIG. 11, the duty ratio of the second DC signal is different from the duty ratio of the first DC signal. At time t1 when the first pulse voltage P1 is applied, application of the second pulse voltage P2 begins. In other words, in the example shown in FIG. 11, the first pulse voltage P1 and the second pulse voltage P2 are applied so as to overlap temporally. Application of the second pulse voltage P2 may be started based on the start of application of the first pulse voltage P1 at time t1.

In the example shown in FIG. 11, the voltage of the first DC signal is VL1 from time t1 to time t2 and VH1 from time t2 to time t4 during time period PDa, which forms one cycle. In other words, during period Ta1, which extends from time t1 to time t2, the first pulse voltage P1 is applied to the substrate support 11. Also, during period Ta2, which extends from time t2 to time t4, application of the first pulse voltage P1 to the substrate support 11 is stopped. With this, time period PDa, which is one cycle of the first DC signal, comes to an end. Simultaneously, at time t4, the voltage of the first DC signal reaches VL1 again, and the next cycle of the first DC signal begins.

Also, in the example shown in FIG. 11, the voltage of the second DC signal is VL2 from time t1 to time t3 and VH2 from time t3 to time t4 during time period PDb, which forms one cycle. In other words, during time period Tb1, which extends from time t1 to time t3, the second pulse voltage P2 is applied to the upper electrode. Also, during time period Tb2, which extends from time t3 to time t4, the application of the second pulse voltage P2 to the upper electrode is stopped. In this way, time period PDb, which forms one cycle of the second DC signal, comes to an end. Simultaneously, at time t4, the voltage of the second DC signal reaches VL2 again, and the next cycle of the second DC signal begins. By repeating these operations, step ST4 in the present example is executed.

In this example, the second pulse voltage P2 is applied so as to overlap with time period Ta1 in which the first pulse voltage P1 is applied. This makes it possible to increase the density of the generated plasma. Also, because charging of the shower head 13 (upper electrode) can be suppressed, discharge at, for example, the gas introduction ports 13c can be suppressed.

In each of the examples described with reference to FIG. 5 to FIG. 11, voltage VH1 and voltage VH2 may be 0 V. Also, voltage VL1 may be a voltage capable of making the potential of the substrate W negative. Voltage VH1 may be a positive voltage or a negative voltage. Also, voltage VL2 may be a voltage capable of making the potential of the upper electrode negative. Voltage VH2 may be a positive voltage or a negative voltage.

In the examples described with reference to FIG. 5 to FIG. 11, the period for the second DC signal is the same as the period for the first DC signal. In other words, in the examples described with reference to FIG. 5 to FIG. 11, time period PDa which forms one cycle for the first DC signal includes a time period Tb1 in which the second pulse voltage P2 is applied. In another example, the first DC signal and the second DC signal may have one period that is twice as long as the other periods or more. In another example, the second pulse voltage P2 may be applied once for every two or more cycles of the first DC signal. Also, the second pulse voltage P2 may be applied two or more times in every cycle for the first DC signal.

In the examples shown in FIG. 5 to FIG. 8, the first DC signal and the second DC signal have the same duty ratio. In other words, the proportion of period Ta1 in period PDa, which forms one cycle for the first DC signal, is equal to the proportion period Tb1 in period PDb, which forms one cycle for the second DC signal. In the examples shown in FIG. 9 to FIG. 11 the first DC signal and the second DC signal have different duty ratios.

The proportion of period Ta1 in period PDa, which forms one cycle for the first DC signal, differs from the proportion of period Tb1 in period PDb, which forms one cycle for the second DC signal. The duty ratios of the first DC signal and the second DC signal are not limited to these examples. For example, the duty ratios for the first DC signal and the second DC signal may be such that period Ta1 and period Tb1 are longer than period Ta2 and the period Tb2, respectively. Also, the duty ratios for the first DC signal and the second DC signal may be such that period Ta1 is longer than period Tb1.

In an exemplary embodiment of the present disclosure, a technique is provided that can control the potential of plasma.

The embodiments described above are provided for explanatory purposes and should not be interpreted as limiting the scope of the present disclosure. Various modifications of these embodiments are possible without departing from the scope and spirit of the present disclosure. For example, instead of a capacitively coupled plasma-type substrate processing apparatus 1, the processing method can be executed by a substrate processing apparatus using different types of plasma such as inductively coupled plasma or microwave plasma.

1. A plasma processing method for plasma-processing a substrate with a plasma processing apparatus having a substrate support and an upper electrode inside a chamber,
the method comprising:
placing the substrate on the substrate support;
supplying a processing gas for processing the substrate to the chamber;
supplying a radio frequency to the upper electrode or the substrate support to generate plasma from the processing gas inside the chamber;
periodically applying a first pulse voltage to the substrate support in a first cycle during a period in which the radio frequency is being supplied; and
periodically applying a second pulse voltage to the upper electrode in a second cycle during the period in which the radio frequency is being supplied.

2. The plasma processing method according to claim 1, wherein in the periodically applying the second pulse voltage, the second pulse voltage is applied to the upper electrode in synchronization with the applying the first pulse voltage.

3. The plasma processing method according to claim 1, wherein the second cycle is 1/n of the first cycle.

4. The plasma processing method according to claim 3, wherein n is 1.

5. The plasma processing method according to claim 3, wherein n is 2 or more.

6. The plasma processing method according to claim 1, wherein the substrate support that is provided inside the chamber is configured to support the substrate.

7. The plasma processing method according to claim 1, wherein the upper electrode positioned inside the chamber is opposite the substrate support.

8. The plasma processing method according to claim 1, wherein the periodically applying the first pulse voltage includes:
starting application of the first pulse voltage at a first point in time, and
ending application of the first pulse voltage at a second point in time after the first point in time, and
the periodically applying the second pulse voltage includes:
starting application of the second pulse voltage at the first point in time, and
ending application of the second pulse voltage at the second point in time.

9. The plasma processing method according to claim 1, wherein the periodically applying the first pulse voltage includes:
starting application of the first pulse voltage at a first point in time, and
ending application of the first pulse voltage at a second point in time after the first point in time, and
the periodically applying the second pulse voltage includes:
starting application of the second pulse voltage between the first point in time and the second point in time, and
ending application of the second pulse voltage at a point in time later than the second point in time.

10. The plasma processing method according to claim 1, wherein the periodically applying the first pulse voltage includes:
starting application of the first pulse voltage at a first point in time, and
ending application of the first pulse voltage at a second point in time after the first point in time, and
the periodically applying the second pulse voltage includes:
starting application of the second pulse voltage at the second point in time, and
ending application of the second pulse voltage at a second point in time after the second point in time.

11. The plasma processing method according to claim 1, wherein periodically applying the first pulse voltage includes:
starting application of the first pulse voltage at a first point in time, and
ending application of the first pulse voltage at a second point in time after the first point in time, and
the periodically applying the second pulse voltage includes:
starting application of the second pulse voltage at a third point in time after the second point in time, and
ending application of the second pulse voltage at a point in time after the third point in time.

12. The plasma processing method according to claim 8, wherein a time interval from the start to the end of application of the second pulse voltage is equal to the time interval from the start to the end of application of the first pulse voltage.

13. The plasma processing method according to claim 9, wherein a time interval from the start to the end of application of the second pulse voltage is longer than the time interval from the start to the end of application of the first pulse voltage.

14. The plasma processing method according to claim 9, wherein a time interval from the start to the end of application of the second pulse voltage is shorter than the time interval from the start to the end of application of the first pulse voltage.

15. The plasma processing method according to claim 1, wherein in the generating the plasma, the radio frequency is supplied to the substrate support.

16. The plasma processing method according to claim 1, wherein in the periodically applying the first pulse voltage, negative voltage is applied to the substrate support as the first pulse voltage.

17. The plasma processing method according to claim 1, wherein in the periodically applying the second pulse voltage, negative voltage is applied to the substrate support as the second pulse voltage.

18. A plasma processing apparatus comprising:
a chamber;
a substrate support provided inside the chamber and configured to support the substrate;
an upper electrode provided inside the chamber opposite the substrate support; and
a control unit, wherein the control unit executes controls to place a substrate on the substrate support, the controls comprising:
supplying a processing gas for processing the substrate to the chamber,
supplying a radio frequency to the upper electrode or the substrate support and generating plasma from the processing gas inside the chamber,
periodically applying a first pulse voltage to the substrate support in a first cycle during a period in which the radio frequency is being supplied, and
periodically applying a second pulse voltage to the upper electrode in a second cycle during the period in which the radio frequency is being supplied.

19. The plasma processing apparatus according to claim 18, wherein the second cycle is 1/n of the first cycle.

20. The plasma processing apparatus according to claim 19, wherein n is 1, or 2 or more.
